(19) United States
(12) Patent Application Publication
(10) Pub. No.: US 2009/0078564 A1
(43) Pub. Date: Mar. 26, 2009

(54) TARGET STRUCTURE AND TARGET HOLDING APPARATUS

(75) Inventors: Keiji Ishibashi, Tokyo (JP); Yoshiaki Daigo, Tokyo (JP)

Correspondence Address: FITZPATRICK CELLA HARPER & SCINTO, 30 ROCKEFELLER PLAZA, NEW YORK, NY, 10112, US

(73) Assignee: CANON ANELVA CORPORATION, Kawasaki-shi (JP)

(21) Appl. No.: 12/208,557

(22) Filed: Sep. 11, 2008

(30) Foreign Application Priority Data
Sep. 25, 2007 (JP) 2007-247523

(51) Int. Cl. C23C 14/00

(52) U.S. Cl. 204/192.15; 204/298.13

(57) ABSTRACT

A target structure is provided which enables sputtering of gallium or gallium-containing material in a molten state to be achieved even when the film deposition rate is increased by increasing the input electric power. A sputtering apparatus including such a target structure is also provided. The target structure includes: a holding section formed from a metal material; and gallium or gallium-containing material placed on the holding section, wherein a surface of the holding section which forms an interface with the gallium or gallium-containing material is formed thereon with a thin film having an angle of contact of not more than 30° to the gallium or gallium-containing material in a molten state. The sputtering apparatus includes this target structure.

### CROSS-REFERENCES TO RELATED APPLICATIONS

This application also claims the benefit of priority from Japanese Patent Application No. 2007-247523 filed Sep. 25, 2007, the entire contents of which is incorporated herein by reference.

### BACKGROUND OF THE INVENTION

1. Field of the Invention

The present invention relates to: a target structure for film deposition by sputtering using a low-melting-point material; a target holding structure; and a sputtering apparatus and a gallium deposit preparing method which use the target structure and the target holding structure.

2. Related Background Art

III (now classified into XIII group) nitride-based compound semiconductors, such as gallium nitride (GaN), are direct bandgap semiconductors which exhibit emission spectra widely ranging from ultraviolet to red when forming light-emitting devices for example. Such compound semiconductors are applied to light-emitting devices including a light-emitting diode (LED) and a laser diode (LD).

Since a compound semiconductor of this type has a wide band gap, a device using such a compound semiconductor can be expected to operate stably at a higher temperature than devices using other semiconductors. For this reason, applications of III (now XIII) nitride-based compound semiconductors to transistors, such as FETs, are being developed intensively.

At present, methods for mass production of III (now XIII group) nitride-based compound semiconductors by using a physical vapor deposition process, such as a reactive sputtering process, are tested for the reason that such a process is excellent in film composition reproducibility and in ease of film thickness control when forming a nitride through a chemical reaction between a target material, such as gallium, and nitrogen gas, and for a like reason.

However, the reactive sputtering process generally requires that a backing plate holding a target be cooled to −20° C. or lower by the use of a chiller for example in order to maintain gallium forming a target material in its solid state because the melting point of gallium is as low as 29.8° C.

In order to enable gallium to maintain its solid state as the target, a gallium target has been proposed which includes a high thermal conductivity petri dish comprising an insulating material or electrically-conductive material which is fixed to a backing plate of copper or stainless steel (SUS304) with a bonding material, such as indium, for gallium to be accommodated in the petri dish (Japanese Patent Application Laid-Open No. H11-172424).

In film deposition by a sputtering process, it is industrially requested that the input electric power be enhanced (for example, an input electric power of not less than 1 kW for a target of 6-in. diameter size) in order to increase the film deposition rate thereby attaining any improvement in production efficiency.

With any one of the gallium targets proposed so far, however, an input of a radio frequency (RF) power of, for example, not less than 200 W for a target of 6-in. diameter size causes the gallium target to begin melting partially during sputtering even when the backing plate of the target is cooled to −20° C. using a chiller or the like. An input of a RF power of 500 W causes the gallium target to melt completely. For this reason, the input electric power has to be limited to prevent gallium from melting from its surface, thus raising a problem that such a high film deposition rate as industrially requested cannot be attained.

That is, it has been a reality that the productivity must be sacrificed by lowering the film deposition rate in order to maintain the gallium target in its solid state.

A film of indium gallium nitride (InGaN) and aluminum gallium nitride (AlGaN) other than GaN are stacked to fabricate a device such as an LED or an LD. In forming such a film by sputtering, indium gallium or aluminum gallium alloy is used for the target. These materials also have low melting points and hence have the same problem as with gallium.

The present invention has been made in view of the foregoing problems. Accordingly, it is an object of the present invention to provide: a target structure which enables sputtering of gallium or gallium-containing material in a molten state to be achieved even when the film deposition rate is increased by increasing the input electric power; and a sputtering apparatus including such a target structure.

Particularly, it is an object of the present invention to provide: a sputtering apparatus which is capable of depositing a gallium or a gallium-containing sputtered film of high quality at a high productivity even when gallium or gallium-containing target material becomes molten as a result of an increase in input electric power for increasing the film deposition rate, the film being free of inclusion of contaminant which is caused by sputtering of a surface of an apparatus holding the target material, which surface is exposed by repelling the target material; and a target for use in the sputtering apparatus.

### SUMMARY OF THE INVENTION

In order to accomplish the foregoing objects, the present invention proposes a target structure comprising: a holding section formed from a metal material; and gallium or gallium-containing material placed on the holding section, wherein a surface of the holding section which forms an interface with the gallium or gallium-containing material is formed thereon with a thin film having an angle of contact of not more than 30° to the gallium or gallium-containing material in a molten state.

The “angle of contact” is the angle which is formed between a liquid surface and a solid surface at a place where a free surface of a stationary liquid contacts a solid wall and which is defined inside the liquid. When the liquid wets the solid (i.e., the liquid has a large adhesive force), the angle of contact is an acute angle, while, when the liquid fails to wet the solid, the angle of contact is an obtuse angle (see “Iwanami's Dictionary of Physics and Chemistry”, edition 1983, p. 727, left column). The “angle of contact” is defined herein as the angle of contact formed at the melting temperature (i.e., melting point) of the target material under a pressure of 1 atm.

The thin film is preferably selected from thin films containing carbon.

In an embodiment of the present invention, the thin film containing carbon is a thin film of diamond-like carbon.

In the target of the present invention described above, the holding section may be formed from copper.

In order to accomplish the foregoing objects, the present invention also proposes a sputtering apparatus having the above-described target structure according to the present invention.

The target structure according to the present invention includes: the holding section formed from a metal material; and the gallium or gallium-containing material placed on the holding section, wherein the surface of the holding section which forms the interface with the gallium or gallium-containing material is formed thereon with the thin film having an angle of contact of not more than 30° to the gallium or gallium-containing material in a molten state. This structure is capable of inhibiting the metal material of the holding section from being exposed during sputtering.

A diamond-like carbon thin film may be employed as the thin film having an angle of contact of not more than 30° to the gallium or gallium-containing material in a molten state. Diamond-like carbon is a material which has excellent adhesion to the metal material forming the holding section, high thermal conductivity, the property of being difficult to sputter due to its hardness and denseness, and good wettability with the gallium or gallium-containing material.

As a result, the target structure according to the present invention enables the gallium or gallium-containing material to be sputtered under a high input electric power condition of not less than 1 kW for a target material of 6-in. diameter size, thereby making it possible to increase the film deposition rate and improve the production efficiency.

Even when the gallium or gallium-containing material begins melting from its surface, the thin film, which is formed on the surface of the holding section which forms the interface with the gallium or gallium-containing material, has an angle of contact of not more than 30° to the gallium or gallium-containing material in a molten state and hence is capable of preventing the surface of the holding section of the metal material from being exposed, thereby making it possible to deposit a sputtered film of good quality free of inclusion of contaminant.

The sputtering apparatus according to the present invention is capable of increasing the film deposition rate, improving the production efficiency and depositing a sputtered film of good quality free of inclusion of contaminant by using the target structure of the present invention.

### BRIEF DESCRIPTION OF THE DRAWINGS

FIG. 1A is a sectional view illustrating one exemplary gallium target structure according to the present invention.

FIG. 1B is an enlarged fragmentary sectional view illustrating the exemplary gallium target structure according to the present invention.

FIG. 2 is a view schematically showing a configuration of one exemplary sputtering apparatus according to the present invention.

### DESCRIPTION OF THE PREFERRED EMBODIMENTS

Hereinafter, preferred embodiments of the present invention will be described with reference to the attached drawings.

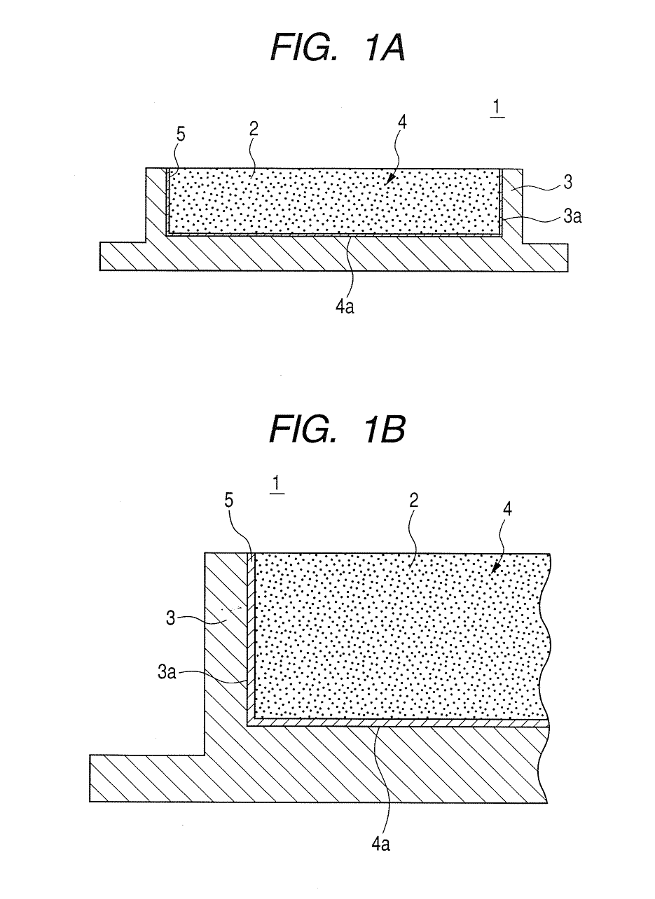

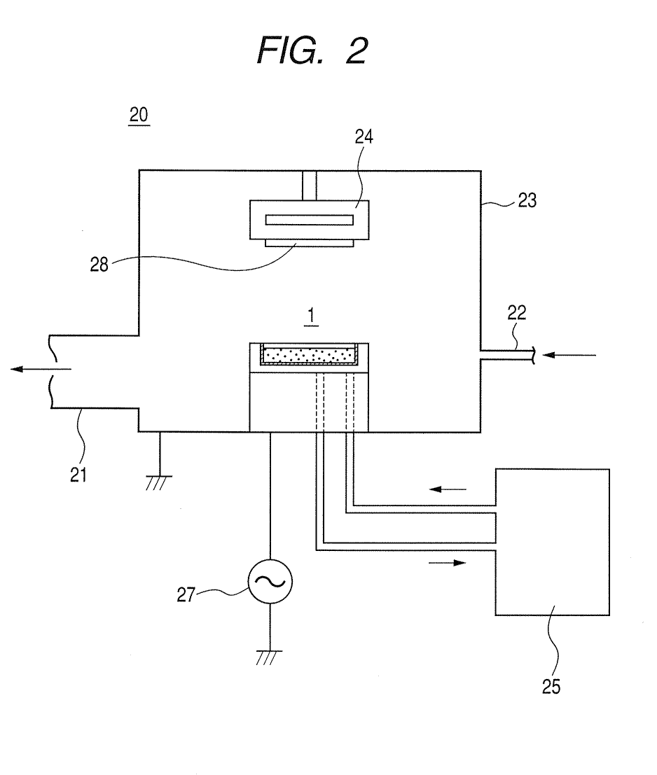

FIG. 1 is an enlarged view showing a gallium target (target structure) 1 placed in a chamber 23 of a sputtering apparatus 20 shown in FIG. 2. Specifically, FIG. 1(A) is an enlarged sectional view of the gallium target 1 and FIG. 1(B) is an enlarged fragmentary view of a portion of the gallium target 1 shown in FIG. 1(A).

The gallium target structure 1 according to the present invention includes a holding section 3 formed from a metal material, and gallium 2 placed on the holding section 3. In the embodiment shown, the holding section 3 has an internal surface coated with diamond-like carbon 5 as a thin film.

In the embodiment shown in FIG. 1, the holding section 3 is formed from copper and substantially disc-shaped in a plan view. In FIG. 1, the holding section 3 has an annular ridge on an upper side thereof and defines a recess 4 inside the annular ridge. Gallium 2 is held in the recess 4 to form the gallium target structure 1 according to the present invention.

The holding section 3 has an interface with gallium 2 which is coated with diamond-like carbon 5. In the embodiment shown, an inner wall surface 3a of the annular ridge, which is an inner peripheral surface of the recess 4, and an inner bottom surface 4a of the recess 4 are coated with diamond-like carbon 5.

The thin film (i.e., diamond-like carbon 5 in the embodiment shown), which is formed on a surface of the holding section 3 forming the interface with gallium 2 and has an angle of contact of not more than 30° to gallium in a molten state, is formed to a thickness such as not to cause peeling thereof and exposure of the holding section 3 and not to impede the effect of cooling gallium 2, as the thin film is formed at the interface between gallium 2 and the holding section 3. The thin film may be formed to a thickness of 0.5 to 5 μm for example. Such a diamond-like carbon thin film can be deposited by a film deposition method utilizing hollow cathode discharge (HCD) for example.

While the holding section 3 is formed from copper according to the present embodiment, other metal material, such as stainless steel (SUS304), may be used to form the holding section 3. In view of the purpose of the present invention, a material having high thermal conductivity, such as copper used in the present embodiment, is desirable.

The sputtering apparatus 20 shown in FIG. 2 is constructed using such a gallium target structure 1.

The sputtering apparatus 20 shown in FIG. 2 is a magnetron sputtering apparatus which includes: the chamber 23 to which a vacuum pumping system 21 and a gas introducing system 22 are connected; the gallium target 1 shown in FIG. 1 which is located in a lower portion of the chamber 23; and a substrate holder 24 located in an upper portion of the chamber 23, the gallium target 1 and the substrate holder 24 being opposed to each other within the chamber 23. When an inert gas for discharge is introduced from the gas introducing system 22, sputtering becomes possible. When a gas, such as nitrogen gas or a mixed gas of nitrogen gas and an inert gas, is introduced from the gas introducing system 22, reactive sputtering becomes possible.

The gallium target structure 1 can be efficiently cooled by an external cooling apparatus 25 having piping through which a coolant flows.

The gallium target structure 1 is connected to a RF power source (13.56 MHz) 27. On the reverse side of the gallium target structure 1, there is provided a magnet assembly which is capable of forming a predetermined magnetic field over the gallium target structure 1 to make magnetron sputtering possible. A substrate 28 on which a film is to be deposited is attached to the side of the substrate holder 24 which faces the gallium target structure 1.

According to the sputtering apparatus 20 thus constructed, the film of diamond-like carbon 5 having high thermal conductivity is formed at the interface at which gallium 2 and the holding section 3 of metal material holding gallium 2, which form the gallium target structure 1, contact each other. Thus, heat generated by gallium 2 during sputtering can be efficiently transferred to the holding section 3 formed from the metal material having high thermal conductivity and, hence, gallium 2 can be cooled sufficiently.

Therefore, it is possible to increase the electric power for sputtering, improve the film deposition rate, and deposit a thin film of a gallium compound at high productivity.

That is, good wettability between gallium 2 and diamond-like carbon 5 can prevent the holding section 3 of copper from being exposed even when gallium 2 begins melting. For this reason, it is possible to avoid inclusion of contaminant into the gallium compound thin film, thereby to deposit the film of good quality.

Particularly, by provision of the thin film having an angle of contact of not more than 30° to gallium in a molten state on the surface of the holding section 3 which forms the interface with gallium 2, the possibility that the metal material of the holding section is exposed during sputtering can be reduced. When the angle of contact of the thin film formed on the surface of the holding section 3 which forms the interface with gallium 2 is more than 30° to gallium in a molten state, the metal material of the holding section is exposed during sputtering, which results in an increased possibility of inclusion of the metal material of the holding section into the thin film deposited by the sputtering apparatus having the gallium target of the present invention. For this reason, such an angle of contact is not preferable.

The target holding structure according to the present invention is also applicable to cases where gallium-containing materials, such as aluminum gallium, indium gallium, gallium phosphide and gallium arsenide, are used. With any material other than the gallium-containing materials which has a low angle of contact to the material of the thin film when in a molten state, use of the target holding structure according to the present invention makes it possible to prevent inclusion of the material of the holding structure.

### COMPARATIVE EXAMPLES

TiN and AlN were employed as materials each having an angle of contact of more than 30° to gallium in a molten state. Surfaces of holding sections 3 of copper each in the form shown in FIG. 1 were coated with TiN and AlN, respectively, by the sputtering process. The holding sections 3 are filled with gallium as shown in FIG. 1 to provide two gallium target structures as comparative examples.

Experimental gallium sputtering was conducted by the above-described magnetron sputtering apparatus shown in FIG. 2 using each of the gallium target structures as the comparative examples.

As a result, the target structure coated with TiN allowed molten gallium to be repelled halfway through the film deposition, so that the holding section 3 was exposed.

Like the target structure coated with TiN, the target structure coated with AlN allowed molten gallium to be repelled halfway through the film deposition. In addition, the color of the holding section 3 was changed to green. Conceivably, this was caused by chemical reaction of Al of AlN.

The basic magnetron sputtering apparatus has been described as an embodiment of the sputtering apparatus according to the present invention. The sputtering apparatus according to the present invention is not limited to such a magnetron sputtering apparatus but may be any other type of sputtering apparatus which uses the above-described gallium target structure 1 placed therein. Such a sputtering apparatus can also offer the same advantage as described above.

What is claimed is:

1. A target structure comprising: a target holding section formed from a metal material; and gallium or gallium-containing target material placed on the target holding section, wherein a surface of the target holding section which forms an interface with the gallium or gallium-containing target material is formed thereon with a thin film having an angle of contact of not more than 30° to the gallium or gallium-containing target material in a molten state.

2. The target structure according to claim 1, wherein the thin film contains carbon.

3. The target structure according to claim 2, wherein the thin film containing carbon is a thin film of diamond-like carbon.

4. The target structure according to claim 1, wherein the holding section is formed from copper.

5. A sputtering apparatus comprising the target structure according to claim 1.

6. A target holding structure comprising: a holding section for holding target material; and a coating film formed on a surface of the holding section, wherein
the coating film is formed from a material having an angle of contact of not more than 30° to a gallium or gallium-containing material in a molten state.

7. A target holding structure comprising: a holding section for holding a target material; and a coating film comprising diamond-like carbon and formed on a surface of the holding section.

8. A method of preparing a gallium deposit, comprising the step of depositing gallium or gallium-containing film by a sputtering process using the target structure according to claim 1.

9. A method of preparing a gallium deposit, comprising the step of depositing gallium or gallium-containing film by a sputtering process using the target holding structure according to claim 6.

10. A method of preparing a gallium deposit, comprising the step of depositing gallium or gallium-containing film by a sputtering process using the target holding structure according to claim 7.
